(19) United States
(12) Patent Application Publication
(10) Pub. No.: US 2007/0075360 A1
(43) Pub. Date: Apr. 5, 2007

(54) Cobalt silicon contact barrier metal process for high density semiconductor power devices

(75) Inventors: Hong Chang, Cupertino, CA (US); Tiesheng Li, San Jose, CA (US); Sung-Shan Tai, San Jose, CA (US); Daniel Ng, Campbell, CA (US); Anup Bhalla, Santa Clara, CA (US)

Correspondence Address: Bo-In Lin, 13445 Mandoli Drive, Los Altos Hills, CA, 94022, US

(73) Assignee: Alpha &Omega Semiconductor, LTD.

(21) Appl. No.: 11/240,255

(22) Filed: Sep. 30, 2005

(51) Int. Cl. H01L 29/78; H01L 21/336

(52) U.S. Cl. 257/330; 438/270; 438/683; 257/384

(57) ABSTRACT

This invention discloses an improved trenched metal oxide semiconductor field effect transistor (MOSFET) cell that includes a trenched gate surrounded by a source region encompassed in a body region above a drain region disposed on a bottom surface of a substrate. The MOSFET cell further includes a source contact opening opened on top of an area extended over the body region and the source region through a protective insulation layer wherein the area further has a cobalt-silicide layer disposed near a top surface of the substrate. The MOSFET cell further includes a Ti/TiN conductive layer covering the area interfacing with the cobalt-silicide layer over the source contact opening. The MOSFET cell further includes a source contact metal layer formed on top of the Ti/TiN conductive layer ready to form source-bonding wires thereon.

### BACKGROUND OF THE INVENTION

1. Field of the Invention

The invention relates generally to the semiconductor power devices. More particularly, this invention relates to an improved and novel contact barrier metal process to manufacture the high-density semiconductor power devices with improved source contact resistance by improving the source contact interfacial layer structures.

2. Description of the Prior Art

With the advent of high efficiency metal oxide semiconductor (MOS) gate devices for hand held electronics power-switching applications leads to a more stringent requirement to further reduce the on-resistance of the MOSFET device. In order to satisfy this requirement, bonding wires of larger diameter to improve the connection between the semiconductor chip and the external leads. With bonding wires of larger diameters, conventional techniques for manufacturing a trenched metal oxide semiconductor field effect transistor (MOSFET) implemented either without a metal barrier or with a titanium/titanium nitride (Ti/TiN) barrier for the metal contacts are therefore confronted with technical difficulties and limitations. Specifically, a high-density trenched semiconductor power device that is implemented without a metal barrier cannot sustain these bonding wires with larger diameters and often leads to yield losses and reliability problems. These problems can be resolved to certain extent by employing a Ti/TiN metal barrier that improves the bonding reliability and increases the production yield. In the semiconductor industry, a barrier layer composed of Ti/TiN has been used as a barrier metal to improve semiconductor contact reliability and to prevent metal “spikes” that can short the source or body region to the gate electrode or crystal defects that lower the quality of the gate oxide layer. FIG. 1A shows a standard implementation of a Ti/TiN barrier layer in a trenched MOSFET device.

Improvements of metal contacts by implementing a Ti/TiN barrier layer have been discloses by Yeh et al. in U.S. Pat. No. 5,783,493 wherein an adhesion layer composed of Ti/TiN is formed in the contact openings followed by a metal deposition forming a contact with the source/drain and other elements. Lin et al. disclose in U.S. Pat. No. 6,177,336 a method for fabricating a metal-oxide semiconductor (MOS) transistor on a semiconductor substrate, comprising a preliminary conductive layer further comprises a Ti/TiN barrier layer, which is conformal to a top surface of the substrate. Williams et al. disclose in U.S. Pat. No. 6,413,822a configuration where a high pressure deposition of the thick metal layer combined with the formation of a barrier layer as a sandwich of Ti and TiN. Method and devices are also disclosed in U.S. Pat. Nos. 5,693,562 and 5,950,090 to manufacture a semiconductor device implementing a barrier layer composed of Ti/TiN to improve the reliability of the contact metal, However, the implementation of a Ti/TiN metal barrier in a trenched MOSFET is at the expense of device performance. A Ti/TiN metal barrier at the contact interface causes an interface doping loss at the silicon-Ti/TiN interface especially for a P-channel trench DMOS that leads to significant on-resistance Rdson and threshold voltage Vt increase and causes a trenched DMOS device to under perform. FIG. 1B shows the comparisons of the on-resistance and threshold voltage of two P-channel devices manufactured with similar process except one without a metal barrier and one with a titanium/titanium nitride (Ti/TiN) barrier for the metal contacts. The diagram clearly shows some changes in the on-resistance and threshold voltage. Such adversely effects to the device performance due the implementation of the Ti/TiN barrier layer for the purpose of improving bonding wire reliability were not considered as significant and mostly unnoticed until recently when the resistance has been significantly reduced due to the shrinking of cell size and increase of number of cell per unit.

For the purpose of overcoming the performance degradations of the semiconductor power devices caused by Ti/TiN metal barrier, process changes are required. In order to achieve the same key performance such as a trenched DMOS with a same Rds under a same threshold voltage Vt, a source contact implant dose has to increase. However, such process changes are costly and of very limited practical usefulness due to the increase in production costs and additional complexities added to the manufacturing processes.

Therefore, a need still exists in the art of power semiconductor device design and manufacture to provide new manufacturing method and device configuration in forming the power devices such that the above discussed problems and limitations can be resolved.

### SUMMARY OF THE PRESENT INVENTION

It is therefore an object of the present invention to provide a new and improved semiconductor power device implemented with a cobalt-silicon metal barrier contact to circumvent the problems of dopant loss at the contact interface such that the limitations of the conventional methods can be overcome.

Specifically, it is an object of the present invention to provide improved MOSFET devices manufactured with a trenched gate by implementing a new and unique CoSi/Ti/TiN metal barrier structure for trenched DMOS. Such device configuration also has a unique process with higher activation temperature window to overcome the bonding related reliability deficiencies and the limitations caused by the DMOS performance degradation as that encountered in the conventional semiconductor power devices.

Briefly in a preferred embodiment this invention discloses a trenched metal oxide semiconductor field effect transistor (MOSFET) cell that includes a trenched gate surrounded by a source region encompassed in a body region above a drain region disposed on a bottom surface of a substrate. The MOSFET cell further includes a source contact opening opened on top of an area extended over the body region and the source region through a protective insulation layer wherein the area further has a cobalt-silicide layer disposed near a top surface of the substrate. The MOSFET cell further includes a Ti/TiN conductive layer covering the area interfacing with the cobalt-silicide layer over the source contact opening. The MOSFET cell further includes a source contact metal layer formed on top of the Ti/TiN conductive layer ready to form source-bonding wires thereon. The MOSFET device further includes a gate contact opening opened on top of the trenched gate through the protective insulation layer and a Ti/TiN conductive layer covering the gate opening in electrical contact with the trenched gate. The MOSFET device further includes a gate contact metal layer formed on top of the Ti/TiN conductive layer ready to form a gate bonding wire thereon.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a cross sectional view of a conventional trenched DMOS device implemented with a Ti/TiN metal barrier.

FIG. 1B shows the Vt and on-resistance changes due to the change of dopant profile at the Si—Ti/TiN interface.

FIG. 2 is a cross sectional view of a trenched DMOS device implemented with CoSi contact barrier metal process according to a process of this invention.

FIG. 3 shows the Vt and on-resistance changes in comparison to the changes of on-resistance and Vt due to the dopant profile changes at the CoSi interface relative to that at the Si—Ti/TiN interface.

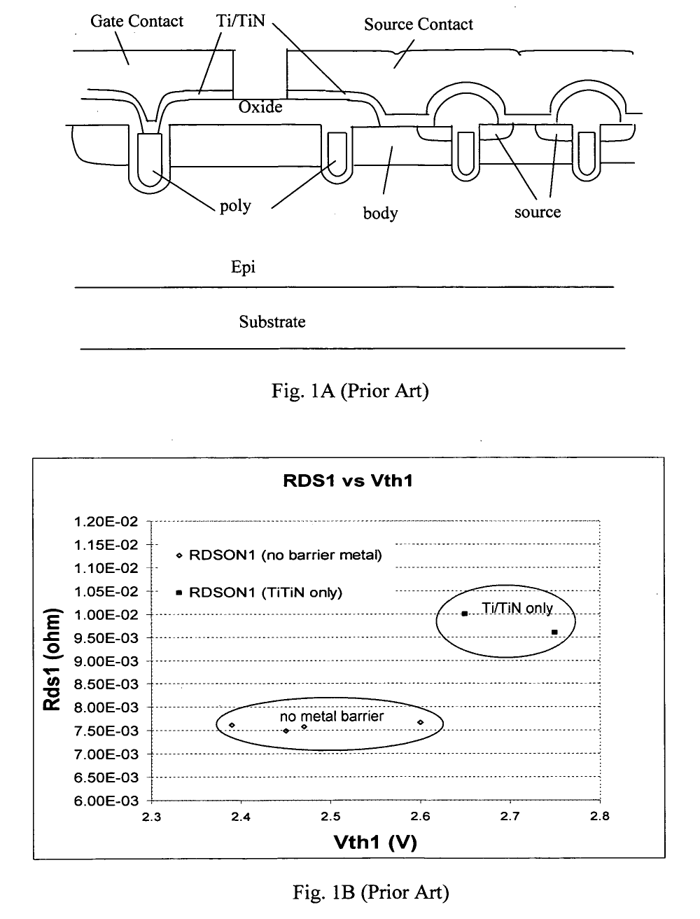

### DETAILED DESCRIPTION OF THE METHOD

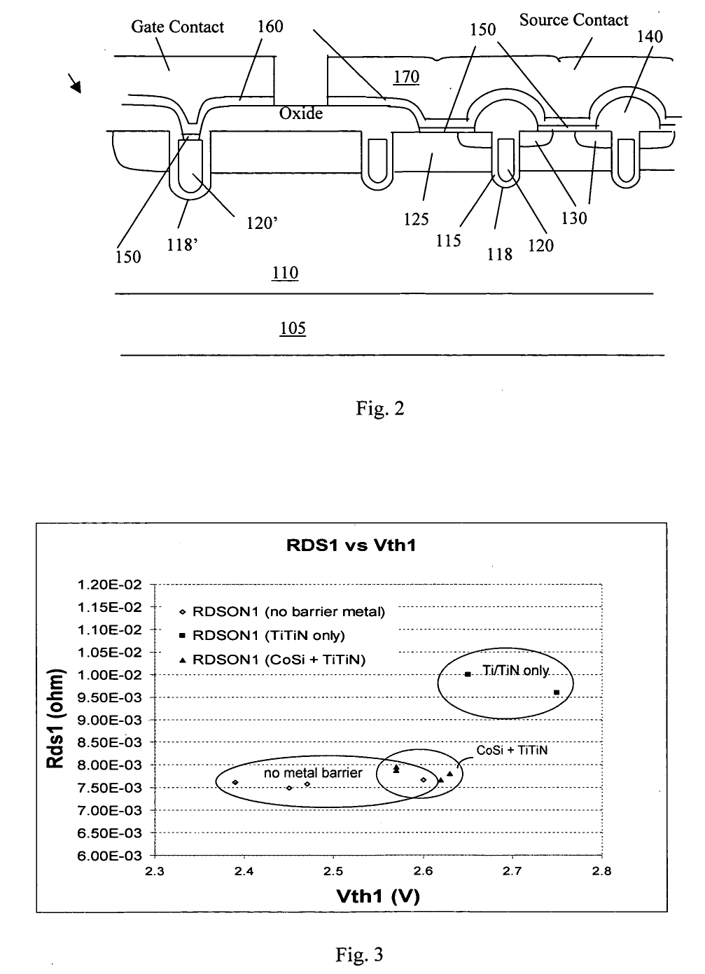

Referring to FIG. 2 for a cross sectional view of a trenched DMOS device 100. The trenched DMOS device 100 is supported on a substrate 105 formed with an epitaxial layer 110. The trenched DMOS device 100 includes a trenched gate 120 disposed in a trench 118 with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 120. The top surface of the semiconductor substrate extending over the top of the trenched gate, the P body regions 125 and the source regions 130 are covered with a dielectric protective layers 140. The trenched DMOS device 100 also includes an insulated gate runner 120′ disposed in a gate runner trench 118′. The gate runner 120′ connects to gate 120 wherein the connections are not specifically shown.

For the purpose of electrically contact the gate 120′ and the source regions 130, a plurality contact openings are opened on the protective insulation layer 140. In order to overcome the problem of dopant loss in the source openings, a cobalt-silicon interface layer 150 is formed near the surface to interface with a Ti/TiN metal barrier layer 160. A contact metal layer 170 is then formed on top of the Ti/TiN barrier layer 160 to form the gate and source contact metals. The CoSi interface layer 150 provided to contact the Ti/TiN metal barrier 160 eliminates the problem of dopant loss thus provide a good source contact. The problems of dopant losses and performance degradations due to increased source contact resistance are therefore resolved. FIG. 3 shows the CoSi interface layer 150 significantly improves the on-resistance of the device compare to the device has Si—Ti/TiN interface.

Various standard manufacturing processes are applied to form the trenched gate, the body regions 125, the source regions 130, the protective insulation layer 140 and opening the contact openings on the insulation layer 140. Followed the opening of the contact openings on the insulation layer 140, a 100 to 300 Angstroms of cobalt is sputtered at the same time into the gate runner 120′ and source 130 and body 125 regions exposed in the openings followed by a rapid temperature anneal (RTA) with an elevated temperature of about 400 to 800° C. for a few seconds. The first RTA temperature used disclosed in this invention is significantly higher than the cobalt-silicon formation in a corresponding CMOS process that is typically 475° C. This is because trench DMOS does not have the vertical limitation as CMOS which allows deeper cobalt alloy depth for better ohmic contact. A wet etch process is used to selectively remove cobalt from the non-contact area. A second RTA temperature with temperature of about 450 to 800° C. is applied post a cobalt wet etch. This process may be skipped if the first RTA temperature is high enough to convert all cobalt into cobalt silicide An unique cobalt-silicon interface layer 150 is thus formed that is beneficial to the DMOS device to prevent the dopant loss that leads to increase source contact resistance. The Ti/TiN layer 160 is then sputtered following a third RTA process by applying a temperature that is dependent on device performance requirements. The third RTA is used to enhance metal-metal interface and release potential tension between the two metal layers. Then a metal layer 170 composed of AlSiCu or AlCu are sputtered on top of the Ti/TiN layer 160 and patterned to form the gate and source metal contacts.

According to above descriptions, this invention further discloses a method for manufacturing a trenched metal oxide semiconductor field effect transistor (MOSFET) cell comprising processing steps to form a trenched gate surrounded by a source region encompassed in a body region above a drain region disposed on a bottom surface of a substrate. The method further includes a step opening a source contact opening on top of an area extended over the body region and the source region through a protective insulation layer and forming a cobalt-silicide layer on the area near a top surface of the substrate. The method further includes a step of forming a Ti/TiN conductive layer for covering and interfacing with the cobalt-silicide layer and over the source contact opening. The method further includes a step of forming contact metal layer on top of the Ti/TiN conductive layer and patterning the contact metal layer into a source metal contact ready to form source bonding wires thereon. The method further includes a step of opening a gate contact opening on top of the trenched gate runner through the protective insulation layer. The method further includes a step of forming a Ti/TiN conductive layer for covering the gate opening in electrical contact with the trenched gate runner. The method further includes a step of forming a contact metal layer on top of the Ti/TiN conductive layer and patterning the contact metal layer into a gate metal contact ready to form a gate bonding wire thereon.

In a preferred embodiment, the step of forming a cobalt-silicide layer on the area near a top surface of the substrate includes a step of sputtering cobalt ions on the area. In another preferred embodiment, the step of sputtering cobalt ions on the area further includes a step of sputtering the cobalt ions to a thickness of approximately 100 to 300 Angstroms. In another preferred embodiment, the step of forming a cobalt-silicide layer on the area near a top surface of the substrate further includes a step of carrying out a cobalt-silicide RTA following the step of sputtering cobalt ions on the area. In another preferred embodiment, the step of forming a cobalt-silicide layer on the area near a top surface of the substrate further includes a step of carrying out a first cobalt-silicide RTA at a temperature substantially higher than 475 degree Celsius following the step of sputtering cobalt ions on the area. In another preferred embodiment, the step of forming a cobalt-silicide layer on the area near a top surface of the substrate further includes a step of carrying out a cobalt wet etch following the first cobalt-silicide RTA. In another preferred embodiment, the step of forming a cobalt-silicide layer on the area near a top surface of the substrate further includes a step of carrying out a second cobalt-silicide RTA at a temperature approximately 450 to 800 degrees Celsius following the cobalt wet etch. In another preferred embodiment, the step of forming a cobalt-silicide layer on the area near a top surface of the substrate further includes a step of carrying out a third cobalt-silicide RTA following the second cobalt-silicide RTA. In another preferred embodiment, the method further includes a step of sputtering a Ti/TiN conductive layer on top of the MOSFET device covering the cobalt-silicide area and the source contact opening. In another preferred embodiment, the method further includes a step of sputtering a metal layer composed of AlSiCu or AlCu on top of the Ti/TiN layer and patterning the metal layer into a source contact metal layer.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

We claim:

1. A trenched metal oxide semiconductor field effect transistor (MOSFET) cell comprising a trenched gate surrounded by a source region encompassed in a body region above a drain region disposed on a bottom surface of a substrate, wherein said MOSFET cell further comprising:
a source contact opening opened on top of an area extended over said body region and said source region through a protective insulation layer wherein said area further comprising a cobalt-silicide layer disposed near a top surface of said substrate.

2. The MOSFET cell of claim 1 further comprising:
a Ti/TiN conductive layer covering said area with said cobalt-silicide layer over said source contact opening.

3. The MOSFET cell of claim 2 further comprising:
a source contact metal layer formed on top of said Ti/TiN conductive layer ready to form source bonding wires thereon.

4. The MOSFET cell of claim 1 further comprising:
a gate contact opening opened on top of said trenched gate through said protective insulation layer.

5. The MOSFET cell of claim 4 further comprising:
a Ti/TiN conductive layer covering said gate opening in electrical contact with said trenched gate.

6. The MOSFET cell of claim 5 further comprising:
a gate contact metal layer formed on top of said Ti/TiN conductive layer ready to form a gate bonding wire thereon.

7. A method for manufacturing a trenched metal oxide semiconductor field effect transistor (MOSFET) cell comprising processing steps to form a trenched gate surrounded by a source region encompassed in a body region above a drain region disposed on a bottom surface of a substrate, wherein method further comprising:
opening a source contact opening on top of an area extended over said body region and said source region through a protective insulation layer and forming a cobalt-silicide layer on said area near a top surface of said substrate.

8. The method of claim 7 further comprising:
forming a Ti/TiN conductive layer for covering said cobalt-silicide layer and over said source contact opening.

9. The method of claim 8 further comprising:
forming contact metal layer on top of said Ti/TiN conductive layer and patterning said contact metal layer into a source metal contact ready to form source bonding wires thereon.

10. The method of claim 7 further comprising:
opening a gate contact opening on top of said trenched gate through said protective insulation layer.

11. The method of claim 10 further comprising:
forming a Ti/TiN conductive layer for covering said gate opening in electrical contact with said trenched gate.

12. The MOSFET cell of claim 11 further comprising:
forming a contact metal layer on top of said Ti/TiN conductive layer and patterning said contact metal layer into a gate metal contact ready to form a gate bonding wire thereon.

13. The method of claim 7 wherein:
said step of forming a cobalt-silicide layer on said area near a top surface of said substrate includes a step of sputtering cobalt ions on said area.

14. The method of claim 13 wherein:
said step of sputtering cobalt ions on said area further comprising sputtering said cobalt ions to a depth of approximately 100 to 300 Angstroms into said substrate.

15. The method of claim 13 wherein:
said step of forming a cobalt-silicide layer on said area near a top surface of said substrate further includes a step of carrying out a cobalt-silicide RTA following said step of sputtering cobalt ions on said area.

16. The method of claim 13 wherein:
said step of forming a cobalt-silicide layer on said area near a top surface of said substrate further includes a step of carrying out a first cobalt-silicide RTA at a temperature substantially higher than 475 degree Celsius following said step of sputtering cobalt ions on said area.

17. The method of claim 16 wherein:
said step of forming a cobalt-silicide layer on said area near a top surface of said substrate further includes a step of carrying out a cobalt wet etch following said first cobalt-silicide RTA.

18. The method of claim 17 wherein:
said step of forming a cobalt-silicide layer on said area near a top surface of said substrate further includes a step of carrying out a second cobalt-silicide RTA at a temperature approximately 450 to 800 degrees Celsius following said cobalt wet etch.

19. The method of claim 18 wherein:
said step of forming a cobalt-silicide layer on said area near a top surface of said substrate further includes a step of carrying out a third cobalt-silicide RTA following said second cobalt-silicide RTA.

20. The method of claim 13 further comprising:
sputtering a Ti/TiN conductive layer on top of said MOSFET device covering said cobalt-silicide area and said source contact opening.

21. The method of claim 20 further comprising:
sputtering a metal layer composed of AlSiCu or AlCu on top of said Ti/TiN layer and patterning said metal layer into a source contact metal layer.
